(19) United States
(12) Patent Application Publication
(10) Pub. No.: US 2008/0124840 A1
(43) Pub. Date: May 29, 2008

(54) Electrical Insulating Layer for Metallic Thermal Interface Material

(76) Inventor: Michael Z. Su, Round Rock, TX (US)

Correspondence Address: TIMOTHY M HONEYCUTT ATTORNEY AT LAW, P O BOX 1577, CYPRESS, TX, 77410, US

(21) Appl. No.: 11/461,305

(22) Filed: Jul. 31, 2006

(51) Int. Cl. H01L 21/62

(52) U.S. Cl. 438/118; 438/763; 257/E21.52

(57) ABSTRACT

Various semiconductor devices and method of manufacturing the same are provided. In one aspect, a method of manufacturing is provided that includes forming an insulating layer on a backside of a semiconductor chip and forming a metallic thermal interface material on the insulating layer. In another aspect, an integrated circuit is provided that includes a semiconductor chip that has a front side and a backside. An insulating layer is on the backside and a metallic thermal interface material is on the insulating layer.

### BACKGROUND OF THE INVENTION

1. Field of the Invention

This invention relates generally to semiconductor processing, and more particularly to apparatus and methods of packaging semiconductor chips.

2. Description of the Related Art

Heat is an enemy of most electronic devices. Integrated circuits, such as microprocessors, can be particularly susceptible to heat-related performance problems or device failure. Over the years, the problem of cooling integrated circuits has been tackled in a variety of ways. For conventional plastic or ceramic packaged integrated circuits, cooling fans, heat fins and even liquid cooling systems have been used, often with great success.

In the past few years, the size and power consumption of integrated circuits has climbed to the point where designers have turned to other ways to shed heat. One of these techniques involves using a metal lid for an integrated circuit package. The goal is to use the high thermal conductivity of the metal lid to ferry heat away from an integrated circuit. Of course, to ensure a conductive heat transfer pathway from the integrated circuit, designers early on placed a thermal paste between the integrated circuit and the lid. More recently though, designers have begun to use a metal layer as thermal interface material in place of a paste.

Metal thermal interface materials have the advantage of higher coefficients of thermal conductivity than the polymers conventionally used as pastes. However, the use of metal thermal interface material has introduced a new technical challenge, namely, the creation of an ohmic pathway into the backside of an integrated circuit. Spurious signals may propagate into the metal lid, and pass through the metal thermal interface material and into the backside of the integrated circuit. The spurious signals may come from cooling fan noise, ground loop spikes, or even electromagnetic interference. The sources of electromagnetic interference may be mobile telephones, radio transmitters, microwave sources and others. The spurious signals can lead to device performance issues or even device failure.

The present invention is directed to overcoming or reducing the effects of one or more of the foregoing disadvantages.

### SUMMARY OF THE INVENTION

In accordance with one aspect of the present invention, a method of manufacturing is provided that includes forming an insulating layer on a backside of a semiconductor chip and forming a metallic thermal interface material on the insulating layer.

In accordance with another aspect of the present invention, a method of manufacturing is provided that includes forming an insulating layer on a backside of a semiconductor chip, forming a metallic thermal interface material on the insulating layer, and placing the semiconductor chip in a package having a metallic lid.

In accordance with another aspect of the present invention, an integrated circuit is provided that includes a semiconductor chip that has a front side and a backside. An insulating layer is on the backside and a metallic thermal interface material is on the insulating layer.

In accordance with another aspect of the present invention, an integrated circuit is provided that includes a package that has a substrate and a metallic lid. A semiconductor chip is provided that has a front side and a backside. The front side is coupled to the substrate. An insulating layer is on the backside and a metallic thermal interface material is on the insulating layer and coupled to the metallic lid.

### BRIEF DESCRIPTION OF THE DRAWINGS

The foregoing and other advantages of the invention will become apparent upon reading the following detailed description and upon reference to the drawings in which:

FIG. 1 is a cross-sectional view of an exemplary conventional semiconductor chip package that is designed to enclose a semiconductor die;

FIG. 2 is a partially-exploded pictorial view of an exemplary embodiment of an integrated circuit package in accordance with the present invention;

FIG. 3 is a sectional view of FIG. 2 taken at section 3-3;

FIG. 4 is a cross-sectional view of an exemplary semiconductor substrate provided with a backside insulating layer in accordance with the present invention;

FIG. 5 is a cross-sectional view of a conventional fixture that may be used to assemble the package depicted in FIGS. 2 and 3 in accordance with the present invention;

FIG. 6 is a pictorial view of a conventional boat that may be used with the fixture depicted in FIG. 5; and

FIG. 7 is a pictorial view of an alignment rack that may be used with the fixture depicted in FIG. 5.

### DETAILED DESCRIPTION OF SPECIFIC EMBODIMENTS

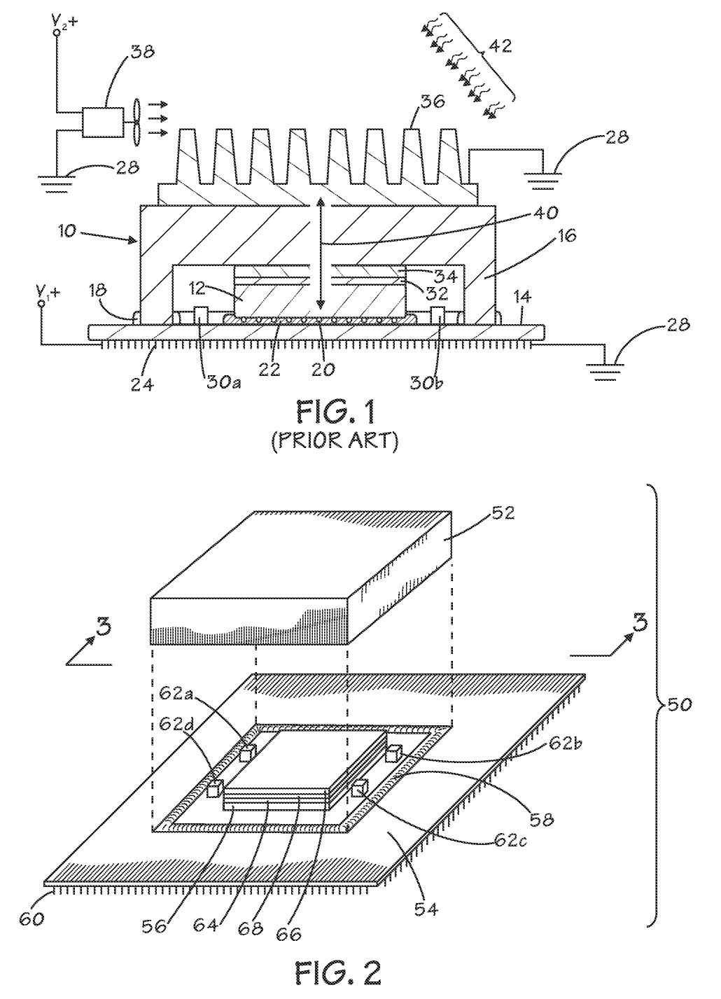

In the drawings described below, reference numerals are generally repeated where identical elements appear in more than one figure. Turning now to the drawings, and in particular to FIG. 1, therein is shown a cross-sectional view of an exemplary conventional semiconductor chip package 10 that is designed to enclose a semiconductor die 12. The package 10 includes a substrate 12 upon which the die 12 is mounted in a flip chip fashion and a metallic lid 16 that is seated on the substrate 14 and encloses the semiconductor die 12. The lid 16 is held in place by way of a bead of adhesive 18. A plurality of solder bumps 24 are disposed on the lower surface of the semiconductor die 12 and establish electrical contact with electrical interconnects (not shown) on the upper surface of the substrate 14. An underfill material 22 is disposed between the semiconductor die 12 and the upper surface of the substrate. Electrical interconnects between the solder bumps and systems external to the package 10 are provided by way of a plurality of pins 24 which project downwardly from the substrate 14 as shown. One or more of the pins 24 are typically connected to a voltage source V₁+ and a ground 28 as shown. One or more filter capacitors 30 are provided on the substrate 14 to provide electrical protection for the semiconductor die 12 in the circuit path that includes V₁+ and ground 28.

The semiconductor die 12 is provided with a backside metallization stack 32 that includes one or more metallic layers. On top of the stack 32 a metallic thermal interface material 34 is positioned. The metallic thermal interface material 34 is designed to provide an advantageous conductive heat transfer pathway from the semiconductor die 12 to the overlying metallic lid 16 and a heat sink 36 positioned on the lid 16. The heat sink 36 is also connected to a system ground 28. A cooling fan 38 is typically used in conjunction with the heat sink 36 and is connected to the common ground 28 and also to a voltage source V₂+.

As noted in the Background Section hereof, the difficulty associated with the system depicted in FIG. 1 is that the incorporation of a metallic thermal interface material 34 provides an ohmic pathway 40 between the semiconductor die 12 and the lid 16 and the overlying heat sink 36. The fall out from this ohmic pathway 40 is that spurious signals may propagate into the heat sink 36 and/or the lid 16 and enter the semiconductor die through the backside stack 32 and adversely impact the performance thereof. For such spurious signals coming through the pathway 40, the filter capacitors 30a and 30b will have little beneficial impact. Some of the sources of spurious signals include, for example, fan noise coming from the cooling fan 38, ground loop spikes through the common ground 28 and the heat sink 36 and electromagnetic interference, as represented by the electromagnetic radiation 42. The electromagnetic radiation 42 may come from a variety of sources, such as, for example, cellular telephones, portable radios, microwave radiation, or other sources. The deleterious effects of the radiation 40 will depend upon the exact configuration of the package 10 and whatever system the package 10 may be connected to as well as the frequency of the radiation 42.

FIG. 2 is a partially-exploded pictorial view of an exemplary embodiment of an integrated circuit package 50 in accordance with one aspect of the present invention. The package 50 is shown partially exploded that is, a lid 52 of the package 50 is shown exploded from an underlying substrate 54. An integrated circuit 56 is mounted on the substrate 54, preferably though not necessarily in a flip chip orientation. The lid 52 is secured to the substrate 54 by way of an adhesive bead 58. A plurality of conductor pins 60 project downwardly from the substrate 54 and are electrically connected to the integrated circuit 56 by way of conductors (not shown). A plurality of filter capacitors 62a, 62b, 62c and 62d are provided to electrically isolate the integrated circuit 56 from certain types of signals coming up through the conductor pins 60. Like the conventional semiconductor die 12 depicted in FIG. 1, the integrated circuit 56 is provided with a backside metallization stack 64 and a metallic thermal interface material 66. However, unlike the conventional design depicted in FIG. 1, the integrated circuit 56 is provided with an insulating layer 68 interposed between the backside metallization 64 and the thermal interface material 66. The insulating layer 68 serves to break the pathway that would otherwise exist between the overlying metallic lid 52 and the integrated circuit 56 of the type depicted and labeled 40 in FIG. 1. In this way, the integrated circuit 56 is electrically isolated from the types of spurious electrical and electromagnetic signals described above in conjunction with FIG. 1.

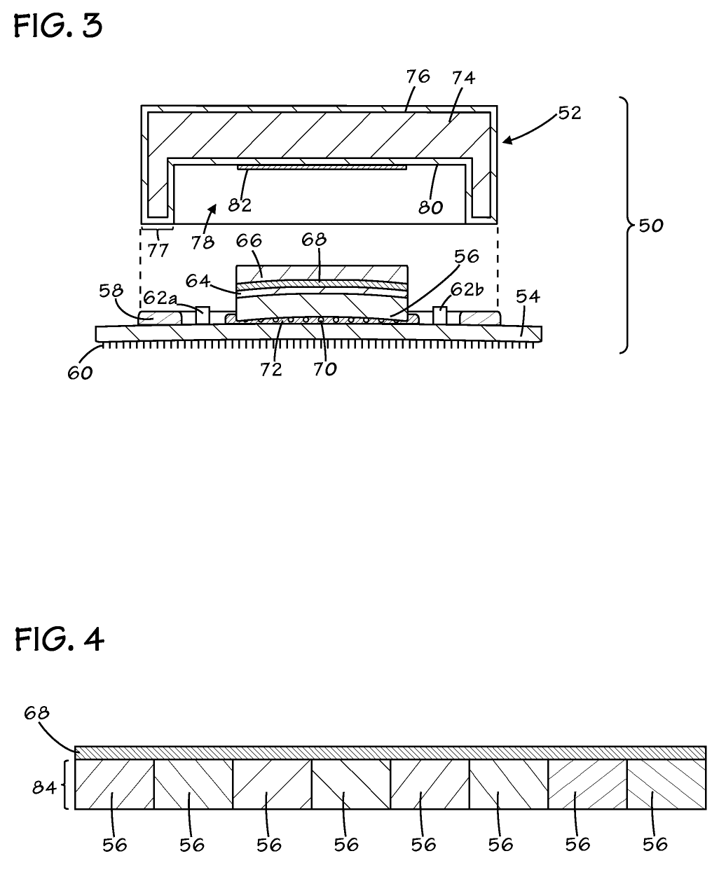

Additional detail regarding the structure of the package 50 may be understood by referring now to FIG. 3, which is a cross sectional view of FIG. 2 taken at section 3-3. Note that because of the location of section 3-3, the filter capacitors 62a and 62b are visible but the filter capacitors 62c and 62d depicted in FIG. 2 are not. The substrate 54, and the combination of the integrated circuit 56, the backside metallization 64, the insulating layer 68 and the thermal interface material 66 are depicted with a warpage as is commonly encountered when the lid 52 is secured to the substrate 54 and the adhesive bead 58 is thermally cured. As noted above, the integrated circuit 56 is advantageously, though not necessarily, mounted to the substrate 54 in a flip chip fashion. In this regard, the integrated circuit 56 may be provided with a plurality of solder bumps 70 that are electrically connected to the conductor pins 60 by way of electrical interconnects (not shown). An underfill material 72 may be provided to serve as a stress cushion between the integrated circuit 56 and the substrate 54. The lid 52 may be composed of a unitary piece of metal or be outfitted as a jacketed design as shown in which a metallic core 74 is surrounded by a metallic jacket 76. In an exemplary embodiment, the core 74 consists of copper and the jacket 76 consists of nickel. The lower surface of the lid 52 consists of a rectangular perimeter wall 77 that is designed to seat on the adhesive bead 58 during assembly. The perimeter wall 77 has a width such that an interior space 78 is provided which encloses the integrated circuit 56 after the lid 52 is attached to the substrate 54.

To facilitate metallurgical bonding between the thermal interface material 66 and a lower surface 80 of the lid interior space 78, a wetting film 82 is provided on the undersurface 80. The wetting film is composed of a material or materials that readily wet the metallic thermal interface material during a thermal reflow process. The desired material or materials for the wetting film 82 will be dictated somewhat by the properties of the thermal interface material. Gold, platinum, palladium or the like are possible materials. Gold readily wets with indium.

The thermal interface material 66 may be composed of a variety of metallic thermal interface materials, such as, for example, indium, gallium, platinum, gold, silver or the like. Mercury, if provided with suitable lateral barriers, such as by way of a metal perimeter for example, could be used as a thermal interface material.

The selection appropriate materials for the backside metallization 64 will depend on the composition of the integrated circuit 56 and the thermal interface material 66. In this exemplary embodiment, the backside metallization 64 consists of an aluminum film formed on the integrated circuit 56, a titanium film formed on the aluminum film, a nickel-vanadium film formed on the titanium film and a gold film formed on the nickel-vanadium film. The aluminum film provides advantageous adhesion with silicon. The titanium film provides a barrier layer to prevent gold from migrating into the integrated circuit 56, the nickel-vanadium film provides desirable adhesion between with gold and the gold film provides a desirable wetting surface for the thermal interface material 66. The stack 64 is formed on the integrated circuit 56 prior to application of the thermal interface material 66.

The insulating layer 68 may be composed of a myriad of different insulating materials, either singly or as in combination or as laminates. For example, the insulating layer may be composed of silicon dioxide, silicon oxynitride, silicon nitride, silicon carbon oxide, polyoxide, high K materials, or even polymeric materials. Again, laminates of these different types of films may be used to form an insulating layer. The appropriate thickness of the insulating layer 68 is largely a matter of design discretion. In an exemplary embodiment, the thickness of the insulating layer 68 may be about 20 to 50 microns. Certainly, the thickness of the insulating layer 68 should be chosen to be large enough in conjunction with the dielectric strength of the material or materials selected for the layer 68 to be able to provide appropriate electrical insulation from the spurious signals that may come through the lid 52.

An exemplary process for forming the insulating layer 68 is depicted in FIG. 4, which is a cross-sectional view of a semiconductor workpiece or wafer 84. The semiconductor workpiece 84 may be processed as necessary to form a plurality of integrated circuits 56, just a few of which are depicted in FIG. 4. Thereafter, the insulating layer 68 may be formed on the semiconductor workpiece 84 by way of well-known chemical vapor deposition or physical vapor deposition steps with or without plasma enhancement. After the insulating layer 68 is formed on the semiconductor workpiece 84, the individual integrated circuits 56 may be divided out of the semiconductor workpiece 84 by well-known cleaving techniques.

An exemplary process flow for assembling the package 50 depicted in FIG. 3 may be understood by referring again to FIG. 3. The process will be described in the context of an indium thermal interface material 66. However, the skilled artisan should appreciate that the process may be easily tailored to other thermal interface materials. Following the mounting of the integrated circuit 56, the adhesive film 58 is applied to the substrate 54. One example of a suitable adhesive 58 is silicone-based thixotropic adhesive, which provides a compliant bond.

A film of flux is next applied to the integrated circuit 56. The purpose of the flux is to facilitate an ultimate metallurgical bonding between the later-applied thermal interface material and the backside metallization stack 64. A rosin-based flux is advantageously used as the flux material. In an exemplary embodiment, the flux may consist of about 20 to 50% by weight rosin mixed with isopropyl alcohol. A jet spray or other suitable application technique may be used to apply the flux.

Next, an indium thermal interface material 66 is applied to the integrated circuit 56. This may be done in at least two ways. In this illustrative embodiment, a preformed film of indium with roughly the same footprint as the integrated circuit 56 is applied to the backside metallization 64. An alternative to be discussed below, involves securing the thermal interface material 66 to the lid 52 and then bringing the lid into contact with the integrated circuit 56. The preformed indium thermal interface material 66 may be supplied in a variety of forms. In an exemplary embodiment, preformed pieces of indium may be supplied on a tape that is positioned on a reel. The tape is advanced and individual preformed pieces or sheets of indium are removed from the tape and placed on the integrated circuit 56. The movement of the indium preforms may be by hand, an automated pick and place mechanism or other type of mechanism. The ultimate uniformity in terms of thickness and material distribution of the indium thermal interface material 66 is a function of the degree of tilt of the lid 52 with respect to the substrate 54. It is desirable for the degree of tilt to be as small as possible. The indium thermal interface material 66 will require a reflow process to establish the desired metallurgical bonding with the lid 52 and the integrated circuit 56. It is desired that the reflow process not adversely impact the tilt characteristics of the lid 52. Accordingly, it is preferable to perform a precure process on the adhesive 58. The goal of the precure process is to partially harden the adhesive 58 before the indium thermal interface material 66 undergoes a reflow. In this way, the reflow process will not cause substantial movement either laterally or vertically of the adhesive film and thus the overlying lid 52 during the indium reflow process.

Prior to precure, flux is applied to the indium film 66 and the lid 52 is seated on the adhesive film 58. A rosin-based flux of the type described elsewhere herein may be used. The seating process may be accomplished by hand with the aid of a guide rack to be described in more detail below or by way of an automated machine. The lid 52 may be preheated prior to seating on the adhesive 58. For example, the lid 52 may be heated to about 100 to 135° C. for 5.0 to 10.0 minutes. The preheated lid 52 is next seated on the adhesive 58. It is anticipated that the temperature of the lid 52 will drop by perhaps 10.0 to 15.0° C. before being seated on the adhesive 58. At the time when the lid 52 is seated on the adhesive 58, the substrate 54 may be positioned in a fixture also to be described in more detail below and a compressive force applied to the lid 52 by way of the fixture. It should be noted that the adhesive 58 may be applied at any point prior to the seating of the lid 52.

With compressive force applied, the substrate 54 and lid combination 52 are subjected to a precure heating. Suitable temperatures and times for the precure will depend on the adhesive and the thermal interface material. Fast curing adhesives may require as little as about 2.0 minutes at 100° C., however, a precure time of up to an hour will be more typical. The precure process will fix the indium bond line thickness, that is, the thickness of the thermal interface material 66.

Following the precure, an indium reflow step is performed. In an exemplary process for indium, the package 50 may be placed in a belt furnace with a nitrogen purge, and heated to about 170 to 190° C. for about 3.0 to 10.0 minutes. The reflow is advantageously performed without compressive force applied to the lid 52. Again, the goal of the indium reflow is to establish metallurgical bonding between the indium thermal interface material 66 and the overlying gold film 82 and the underlying backside metallization stack 64.

Following the indium reflow step, the adhesive film 58 undergoes a final curing process. The curing process is performed without compressive force applied to the lid 52. The final cure may be performed at about 125° C. for about 1.5 hours. Again the temperature and time will depend on the adhesive used.

In the process flow described elsewhere herein in conjunction with FIG. 3, it was noted that a fixture may be used to hold an integrated circuit package, such as the package 50, during various process steps. An exemplary embodiment of such a fixture 90 is depicted in FIG. 50, which is a cross-sectional view. A number of integrated circuit packages are depicted, however only one of the packages 50 is provided with element numbering. The description that follows focuses on the package 50, but is illustrative of any packages held by the fixture 90. The fixture 90 includes a base plate 92 upon which the circuit package 50 is seated. A middle plate 94 is designed to seat on top of the circuit package 50. The middle plate 94 is provided with a compliant sheet 96 composed of rubber or other compliant material. The middle plate 94 is brought into secure engagement with the upper surfaces of the circuit package 50 by way of a top plate 98 that includes a plurality of springs 100. Pressure is applied downward on the top plate 98 by an automated machine or manual clamps and results in a downward force transmitted through the middle plate 94 to the circuit package 50.

The assembly of the circuit package 50 involves a number of process steps that are routinely carried out in different locations. Accordingly, a rack or boat 102 is utilized to hold the circuit package 10 during movement between various processing areas. As better seen in FIG. 6, which is a pictorial view, the boat 102 includes a plurality of openings 104 and two upwardly-projecting posts 106 at each of the corners of the openings 104. The function of the posts 106 is to engage corners of the substrate 54 of the package 50 and thereby restrain yawing movements of the package 50.

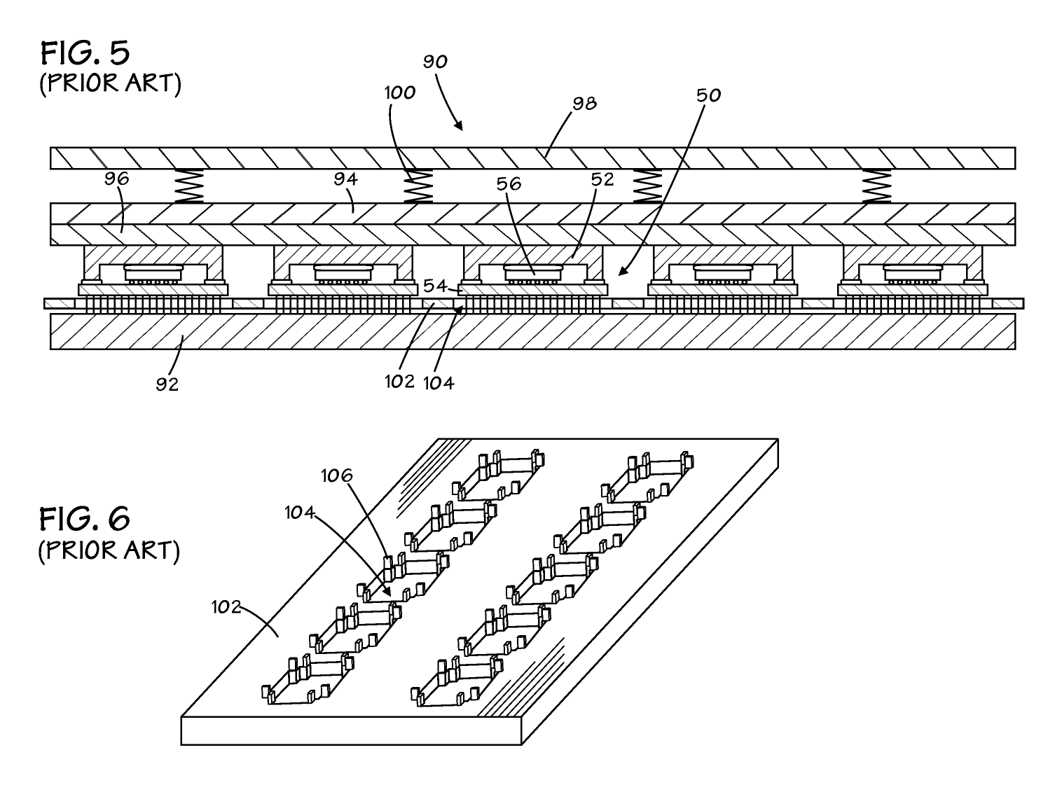

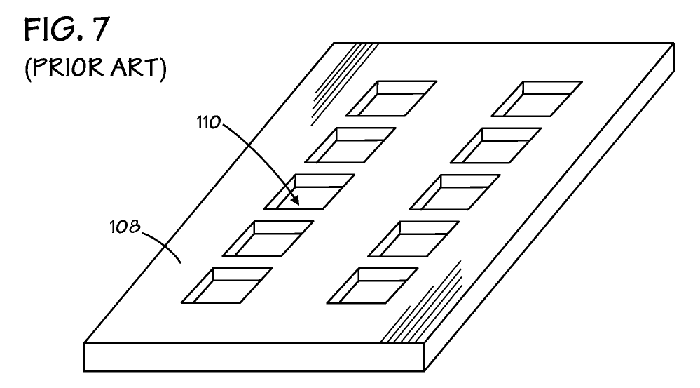

An optional lid alignment plate 108 is depicted in FIG. 7. The alignment plate 108 may be used to facilitate placement of the lid 52 on the substrate 54 of the package 50. With the alignment plate 108 temporarily placed over the package 52 and the base plate 92 (See FIG. 5), the lid 52 is dropped in one of the openings 110 of the alignment plate 108 and seated on the substrate 54. The alignment plate 108 may be removed prior to positioning of the middle and top plates 94 and 98 depicted in FIG. 5.

As noted above in conjunction with FIG. 3, the indium thermal interface material 66 may be first applied to the integrated circuit 56 and the lid 52 thereafter seated on the substrate 54. However, in another option, the thermal interface material may be preattached to the lid 52. Again using indium as an example, an indium preform film or foil 66 is preattached to the lid 52. The method of applying the preattached indium thermal interface material 66 is variable. However, in an illustrative embodiment, the preattachment involves applying a flux to the underside 80 of the lid 52, placing an indium piece or foil 66 on the underside 80, performing a reflow heating step, applying a finishing flux to the reflowed indium foil 66, performing another reflow heating step, performing a cleaning step to remove excess flux, performing a stamping or “coining” of the indium foil 66 to achieve a desired thickness of the indium foil 66 and, finally, applying a layer of rosin-based flux to the coined indium foil 66.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

1. A method of manufacturing, comprising:
forming an insulating layer on a backside of a semiconductor chip; and
forming a metallic thermal interface material on the insulating layer, the insulating layer electrically insulating the backside of the semiconductor chip from the metallic thermal interface material.

2. The method of claim 1, comprising mounting a front side of the semiconductor chip to a substrate.

3. The method of claim 2, comprising placing a lid over the semiconductor chip.

4. The method of claim 3, comprising securing the lid to the substrate with an adhesive.

5. The method of claim 1, comprising reflowing the thermal interface material.

6. The method of claim 1, wherein the forming of the insulating layer comprises a forming a laminate of at least two insulating films.

7. The method of claim 1, wherein the semiconductor chip initially comprises part of a semiconductor wafer, the method comprising forming the insulating layer on the semiconductor wafer and then cleaving the semiconductor chip from the semiconductor wafer.

8. A method of manufacturing, comprising:
forming an insulating layer on a backside of a semiconductor chip;
forming a metallic thermal interface material on the insulating layer; and
placing the semiconductor chip in a package having a metallic lid, the insulating layer electrically insulating the backside of the semiconductor chip from the metallic thermal interface material and the metallic lid.

9. The method of claim 8, wherein the package includes a substrate, the method comprising mounting a front side of the semiconductor chip to the substrate and placing the metallic lid over the semiconductor chip.

10. The method of claim 9, comprising securing the lid to the substrate with an adhesive.

11. The method of claim 8, comprising reflowing the metallic thermal interface material.

12. The method of claim 8, wherein the forming of the insulating layer comprises forming a laminate of at least two insulating films.

13. The method of claim 8, wherein the semiconductor chip initially comprises part of a semiconductor wafer, the method comprising forming the insulating layer on the semiconductor wafer and then cleaving the semiconductor chip from the semiconductor wafer.

14-21. (canceled)

22. A method of manufacturing, comprising:
forming an insulating layer on a backside of a semiconductor chip;
forming an indium thermal interface material on the insulating layer; and
placing the semiconductor chip in a package having a lid including a nickel coated copper lid, the insulating layer electrically insulating the backside of the semiconductor chip from the indium thermal interface material and the lid.

23. The method of claim 22, wherein the package includes a substrate, the method comprising mounting a front side of the semiconductor chip to the substrate and placing the lid over the semiconductor chip.

24. The method of claim 23, comprising securing the lid to the substrate with an adhesive.

25. The method of claim 22, comprising reflowing the indium thermal interface material.

26. The method of claim 22, wherein the forming of the insulating layer comprises forming a laminate of at least two insulating films.

27. The method of claim 22, wherein the semiconductor chip initially comprises part of a semiconductor wafer, the method comprising forming the insulating layer on the semiconductor wafer and then cleaving the semiconductor chip from the semiconductor wafer.
